(19) United States
(12) Patent Application Publication
(10) Pub. No.: US 2013/0141161 A1
(43) Pub. Date: Jun. 6, 2013

(54) POWER AMPLIFIER

(71) Applicants: Norihisa OTANI, Yokohama (JP); Eiichiro Otobe, Yokohama (JP)

(72) Inventors: Norihisa OTANI, Yokohama (JP); Eiichiro Otobe, Yokohama (JP)

(21) Appl. No.: 13/612,460

(22) Filed: Sep. 12, 2012

(30) Foreign Application Priority Data
Dec. 1, 2011 (JP) 2011-263748

(51) Int. Cl. H03F 3/20

(52) U.S. Cl. 330/185

(57) ABSTRACT

There is provided a power amplifier capable of compensating for a distortion without deteriorating a gain of input voltage. The power amplifier includes an input terminal to which an input voltage is applied; a class AB power amplification circuit connected to the input terminal; and an element connected between the input terminal and the class AB power amplification circuit, turned on when the input voltage is equal to or greater than a predetermined value, and varying impedance thereof according to the input voltage.

### CROSS-REFERENCE TO RELATED APPLICATIONS

This application claims the priority of Japanese Patent Application No. 2011-263748 filed on Dec. 1, 2011, in the Japan Patent Office, the disclosure of which is incorporated herein by reference.

### BACKGROUND OF THE INVENTION

1. Field of the Invention

The present invention relates to a power amplifier.

2. Description of the Related Art

According to the related art, a technology providing a linear compensation circuit for amplitude distortion at a low input level in a class AB or class B power amplifier and realizing a wireless device having high frequency efficiency is disclosed in Patent Document 1 below.

However, in the technology disclosed in Patent Document 1, a resistor (R1) 3 is connected between an input terminal 1 and a linear compensation circuit 7, such that distortion is compensated for according to a voltage division of the resistor (R1) 3 and a resistor (R2) 4 (FIG. 1 of Patent Document 1). Therefore, in the case of a low input level, an input/output voltage ratio of a distortion compensation circuit increases, and in the case of a high input level, the input/output voltage ratio decreases. Therefore, in order to operate the power amplifier with the low input level and with the high input level, the resistor (R1) 3 is necessarily installed and the input voltage is required to be input to the linear compensation circuit 7 through the resistor (R1) 3. As the resistor (R1) 3 is installed, a voltage gain of the input voltage is reduced to lead deterioration in power added efficiency (PAE).

### RELATED ART DOCUMENT

(Patent Document 1) Japanese Utility Model Laid-Open Publication No. 1993-23612

### SUMMARY OF THE INVENTION

An aspect of the present invention provides a newly improved power amplifier capable of compensating for distortion, without deteriorating a gain of an input voltage.

According to an aspect of the present invention, there is provided a power amplifier including: an input terminal to which an input voltage is applied; a class AB power amplification circuit connected to the input terminal; and an element connected between the input terminal and the class AB power amplification circuit, turned on when the input voltage is equal to or greater than a predetermined value, and varying impedance thereof according to the input voltage.

According to the configuration as described above, the class AB power amplification circuit may be directly connected to the input terminal, and the element may be turned on when the input voltage is equal to or greater than a predetermined value and impedance thereof may be varied according to the input voltage. Therefore, distortion may be compensated for without deteriorating a gain of the input voltage.

When the element is turned off, the input voltage may be directly input to the power amplification circuit. According to the configuration as described above, when the element is turned off, since the input voltage is directly input to the power amplification circuit, power added efficiency (PAE) may be improved without deteriorating the gain of the input voltage.

The element may include two diodes connected to each other in parallel. According to the configuration as described above, the element may be turned on when the input voltage is equal to or greater than a predetermined value and impedance thereof may be varied according to the input voltage.

The element may include two transistors connected to each other in parallel. According to the configuration as described above, the element may be turned on when the input voltage is equal to or greater than a predetermined value and impedance thereof may be varied according to the input voltage.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram showing a class A high frequency power amplification circuit;

FIG. 2 is a characteristic diagram showing a gain characteristic of the high frequency power amplification circuit shown in FIG. 1;

FIG. 3 is a diagram showing a class AB high frequency power amplification circuit;

FIG. 4 is a characteristic diagram showing a gain characteristic of the high frequency power amplification circuit shown in FIG. 3;

FIG. 5 is a diagram showing a configuration of a power amplifier according to an embodiment of the present invention;

FIG. 6 is a characteristic diagram describing that the gain characteristic of the class AB high frequency power amplification circuit is flattened by the configuration of the power amplifier shown in FIG. 5;

FIG. 7 is a diagram showing an example in which a pre-distorter includes two diodes (anti-parallel diodes);

FIG. 8 is a diagram showing an example in which the pre-distorter includes two transistors; and

FIG. 9 is a characteristic diagram showing an example in which an output characteristic of the class AB high frequency power amplification circuit is improved by using the pre-distorter shown in FIG. 7.

### DETAILED DESCRIPTION OF THE INVENTION

Hereinafter, embodiments of the present invention will be described in detail with reference to the accompanying drawings. In addition, like reference numerals designate like components having substantially the same constitution and function in the specification and the drawings of the present invention. Therefore, an overlapped description thereof will be omitted.

### 1. First Embodiment

[Basic Technology]

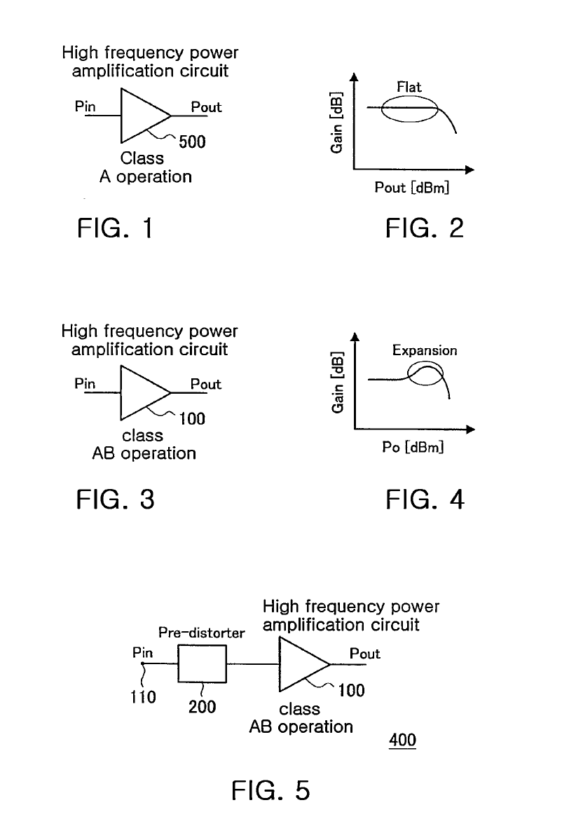

First, a basic technology of the present invention will be described with reference to FIG. 1. FIG. 1 is a diagram showing a class A high frequency power amplification circuit 500. In addition, FIG. 2 is a characteristic diagram showing a gain characteristic of the class A high frequency power amplification circuit 500 shown in FIG. 1. Here, a class A high frequency power amplification circuit means a high frequency power amplification circuit that performs a class A operation.

As shown in FIG. 2, since the gain characteristic of the class A high frequency power amplification circuit 500 is flat, an efficiency of the high frequency power amplification circuit 500 may be deteriorated, while distortion characteristics thereof may be excellent.

Meanwhile, FIG. 3 is a diagram showing a class AB high frequency power amplification circuit 100. In addition, FIG.

4 is a characteristic diagram showing a gain characteristic of the class AB high frequency power amplification circuit 100 shown in FIG. 3. Here, a class AB high frequency power amplification circuit means a high frequency power amplification circuit that performs a class AB operation.

As shown in FIG. 4, since the gain characteristic of the class AB high frequency power amplification circuit 100 is expanded, an efficiency of the class AB high frequency power amplification circuit 100 may be excellent, while distortion characteristics thereof may be deteriorated.

In the present embodiment, the gain characteristic of the class AB high frequency power amplification circuit 100 is suppressed from being expanded, whereby the gain characteristic thereof is flattened. Hereinafter, it will be described in detail.

[Configuration Example of Embodiment]

FIG. 5 is a diagram showing a configuration of a high frequency power amplifier 400 according to an embodiment of the present invention. As shown in FIG. 5, a pre-distorter 200 is located in front of the class AB high frequency power amplification circuit 100 between an input terminal 110 to which an input voltage is applied and the class AB high frequency power amplification circuit 100. The pre-distorter 200 may serve to suppress a gain expansion, a gain characteristic of the class AB high frequency power amplification circuit 100.

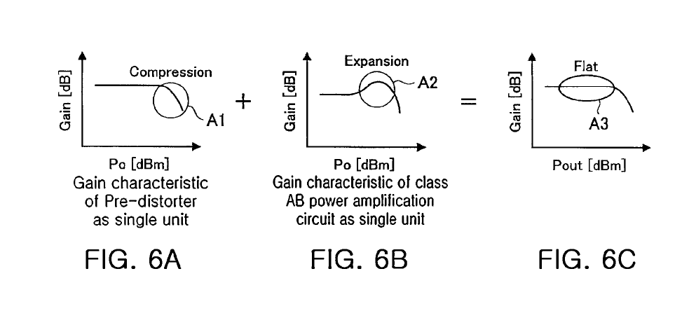

FIG. 6 is a characteristic diagram describing that the gain characteristic of the class AB high frequency power amplification circuit 100 is flattened by the configuration of the power amplifier shown in FIG. 5. Here, FIG. 6A is a characteristic diagram showing a gain characteristic of the pre-distorter 200, a single unit. As shown in FIG. 6A, in the gain characteristic of the pre-distorter 200 as a single unit, a gain compression may be generated in a region denoted by A1 of FIG. 6A.

In addition, FIG. 6B is a characteristic diagram showing the gain characteristic of the class AB high frequency power amplification circuit 100 as a single unit. As shown in FIG. 6B, in the gain characteristic of the class AB high frequency power amplification circuit 100 as a single unit, a gain expansion may be generated in a region denoted by A2 of FIG. 6B, similar to the gain characteristic shown in FIG. 4.

FIG. 6C is a characteristic diagram showing a gain characteristic formed by overlapping the gain characteristic shown in FIG. 6A with that shown in FIG. 6B. As shown in FIG. 6C, when the gain characteristics of FIG. 6A and FIG. 6B are overlapped with each other, the gain expansion generated in region A2 of the class AB high frequency power amplification circuit 100 is adjusted due to the gain compression in region A1 of the pre-distorter 200, such that a flat gain characteristic may be realized as shown in a region denoted by A3 shown in FIG. 6C.

Therefore, in the class AB high frequency power amplification circuit 100, a flat gain characteristic may also be realized and both of distortion characteristics and efficiency may also be improved.

[Configuration Example of Pre-distorter]

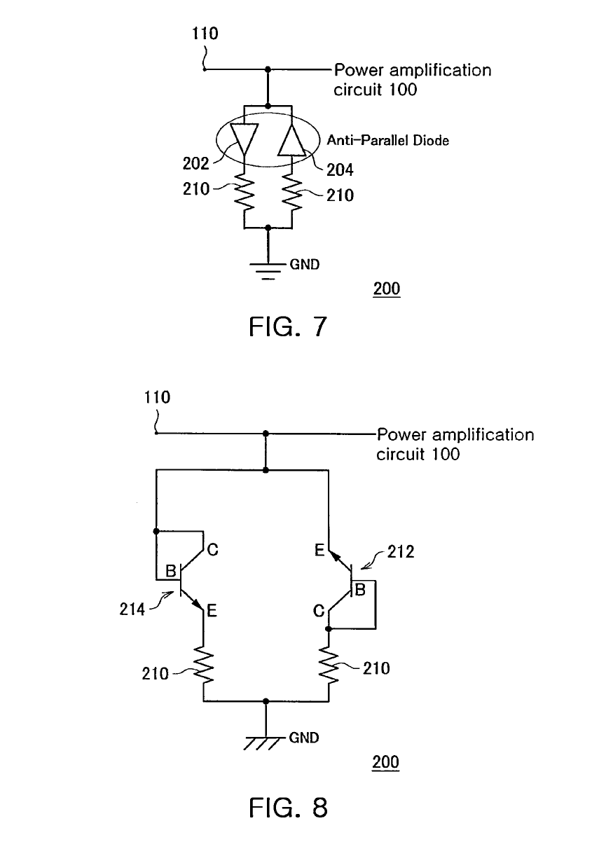

Next, a configuration of the pre-distorter 200 will be described. FIG. 7 is a diagram showing an example in which the pre-distorter 200 includes two diodes 202 and 204 (anti-parallel diodes).

As shown in FIG. 7, the two diodes 202 and 204 are connected to each other in parallel in reverse directions. In addition, respective resistors 210 are arranged between the respective diodes 202 and 204 and a ground potential GND.

According to this configuration, when an input voltage to the pre-distorter 200 is equal to or greater than a predetermined value, the diodes 202 and 204 are turned on, such that current may flow through the diodes 202 and 204. Therefore, the gain compression may be generated in region A1 of FIG. 6A. Therefore, the gain expansion in region A2 of FIG. 6B may be suppressed. Therefore, the gain characteristic may be flattened, as shown in FIG. 6C.

When an input voltage Pin to the pre-distorter 200 decreases, impedance of the diodes 202 and 204 may increase. When the input voltage Pin is low and the diodes 202 and 204 are turned off, the input voltage Pin may be input to the class AB high frequency power amplification circuit 100 as it is.

Meanwhile, when the input voltage Pin increases, the impedance of the diodes 202 and 204 may decrease. Therefore, the gain compression may be generated in region A1 of FIG. 6A according to a value of the resistor 210. In the present embodiment, therefore, the gain compression may be generated, particularly, in the case in which the input voltage is high. Therefore, as shown in FIG. 6B, the gain expansion generated in the region in which the input voltage is high may be surely suppressed.

Here, a gain compression characteristic may be varied according to the value of the resistor 210. When the value of the resistor 210 is high, the gain compression may decrease. Meanwhile, when the value of the resistor 210 is low, the gain compression may increase. Therefore, the value of the resistor 210 is optimally set according to the characteristic of the class AB high frequency power amplification circuit 100, whereby the gain characteristic may be flattened, as shown in FIG. 6C.

According to the embodiment of the present invention as described above, in the case in which a voltage level of the input voltage is low, the input/output voltage ratio may be close to 1, whereas, in the case in which the voltage level of the input voltage is high, the input/output voltage ratio is reduced below 1. Therefore, when the voltage level of the input voltage is high, a distortion compensation circuit may be operated, thereby improving linearity of the high frequency power amplifier.

In addition, according to the configuration of the embodiment of the present invention, elements, such as the resistors and the like, are not inserted between the input terminal to which the input voltage is input and the pre-distorter 200, such that the gain of the input voltage may not be deteriorated. Therefore, as compared to the configuration in which elements, such as the resistors and the like, are inserted between the input terminal and the pre-distorter 200, power added efficiency (PAE) may be significantly improved according to the embodiment of the present invention.

In addition, FIG. 8 is a diagram showing an example in which the pre-distorter 200 includes two transistors 210 and 212. As shown in FIG. 8, the two transistors 210 and 212 are connected to each other in parallel.

Even in the configuration shown in FIG. 8, when input voltage input to the pre-distorter 200 is equal to or greater than a predetermined value, the transistors 212 and 214 are operated such that current may flow through the transistors 212 and 214. Therefore, the gain compression may be generated in region A1 of FIG. 6A. Therefore, the gain expansion generated in region A2 of FIG. 6B may be suppressed. Thereby, the gain characteristic may be flattened, as shown in FIG. 6C.

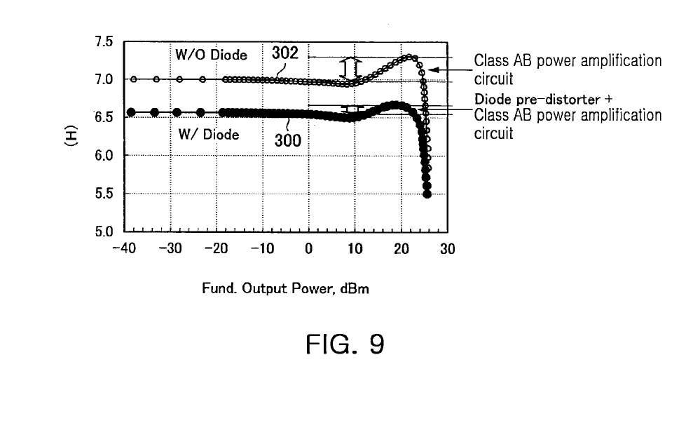

FIG. 9 is a characteristic diagram showing an example in which an output characteristic of the class AB high frequency power amplification circuit 100 is improved using the pre-distorter 200 shown in FIG. 7. In FIG. 9, a characteristic 302 may denote the output characteristics of the class AB high frequency power amplification circuit as a single unit. In addition, a characteristic 300 may show the output characteristic of the class AB high frequency power amplification circuit 100 in the case in which the pre-distorter 200 shown in FIG. 7 is installed in front of the class AB high frequency power amplification circuit 100. As such, the pre-distorter 200 is installed in front of the class AB high frequency power amplification circuit 100, the gain characteristic of the class AB high frequency power amplification circuit 100 may be flattened, particularly, in the region in which a voltage level is high.

As set forth above, according to the embodiments of the present invention, distortion compensation maybe realized and gain deterioration in the input voltage may be suppressed through a simple circuit configuration, to thereby increase power added efficiency (PAE). Therefore, a high frequency power amplifier having high efficiency may be realized through a simple configuration.

As set forth above, according to the embodiment of the present invention, the power amplifier capable of compensating for the distortion, without deteriorating the gain of the input voltage, can be provided.

While the present invention has been shown and described in connection with the embodiments, it will be apparent to those skilled in the art that modifications and variations can be made without departing from the spirit and scope of the invention as defined by the appended claims.

What is claimed is:

1. A power amplifier comprising:
an input terminal to which an input voltage is applied;
a class AB power amplification circuit connected to the input terminal; and
an element connected between the input terminal and the class AB power amplification circuit, turned on when the input voltage is equal to or greater than a predetermined value, and varying impedance thereof according to the input voltage.

2. The power amplifier of claim 1, wherein when the element is turned off, the input voltage is directly input to the power amplification circuit.

3. The power amplifier of claim 1, wherein the element includes two diodes connected to each other in parallel.

4. The power amplifier of claim 1, wherein the element includes two transistors connected to each other in parallel.
